(19) United States
(12) Patent Application Publication
(10) Pub. No.: US 2019/0363670 A1
(43) Pub. Date: Nov. 28, 2019

(54) TARPAULIN SOLAR ENERGY GENERATION SYSTEM AND SOLAR TENT

(71) Applicant: MiaSole Photovoltaic Technology Co., Ltd., Beijing (CN)

(72) Inventors: Hui Li, Beijing (CN); Dongdong Shen, Beijing (CN); Xue Wang, Beijing (CN)

(21) Appl. No.: 16/115,345

(22) Filed: Aug. 28, 2018

(30) Foreign Application Priority Data
May 25, 2018 (CN) 201820791630.9

(51) Int. Cl. H02S 30/20; H02S 40/30; H02S 40/38; H01L 31/046; H01L 31/032; E04H 15/02

(52) U.S. Cl. CPC H02S 30/20; H02S 40/30; H02S 40/38; B62D 33/04; H01L 31/0322; E04H 15/02; H01L 31/046

(57) ABSTRACT

The embodiments of the present disclosure provide a tarpaulin solar energy generation system and a solar tent. In the tarpaulin solar energy generation system, one or more solar components are fixed on the tarpaulin and adapted to receive light energy, and a controller is connected to each of the solar components and an energy storage battery and adapted to convert electrical energy generated by the solar components and to store the converted electrical energy in the energy storage battery.

### CROSS-REFERENCE TO RELATED APPLICATION

This application claims a priority to Chinese Patent Application No. 201820791630.9 filed on May 25, 2018, the disclosures of which are incorporated in their entirety by reference herein.

### TECHNICAL FIELD

The present disclosure relates to the field of photovoltaic power generation technology, in particular to a tarpaulin solar energy generation system.

### BACKGROUND

At present, solar vehicles are equipped on roofs thereof with solar components which can replenish electricity for an energy storage system of the vehicle in case of illumination. The mounting of the solar components on the roof is usually done by mounting a fixed holder on the roof and then mounting the solar components on the fixed holder. However, this solar energy generation system not only has a troublesome mounting process, but also increases the weight of the vehicle body and affects driving safety. It can be expected that the solar vehicle sometimes cannot reach a scheduled place where people do field or outdoor activities, and lack of electricity will bring a lot of inconvenience to people's activities. Furthermore, if there is bad weather, such as a heavy rain or a blazing sun, the lack of electricity not only affects people's normal activities, but also even brings harm to people's health.

### SUMMARY

In a first aspect, an embodiment of the present disclosure provides a tarpaulin solar energy generation system applied to one or more loads inside a vehicle or one or more outdoor devices, the tarpaulin solar energy generation system including a tarpaulin, one or more solar components, a controller and an energy storage battery; the one or more solar components are secured to the tarpaulin and adapted to receive light energy; and the controller is connected to each of the energy storage battery and the solar components and adapted to convert electrical energy generated by the solar components and to store the converted electrical energy in the energy storage battery.

According to one possible embodiment of the present disclosure, one or more mounting holes for securing the tarpaulin to the vehicle or the one or more outdoor devices are provided on one or more sides of a plurality of sides of the tarpaulin.

According to one possible embodiment of the present disclosure, each of the one or more mounting holes is provided with a metal ring fixed therein.

According to one possible embodiment of the present disclosure, the metal ring is a ring made of aluminum.

According to one possible embodiment of the present disclosure, the solar component is a flexible solar component.

According to one possible embodiment of the present disclosure, the flexible solar component includes a flexible thin film solar cell.

According to one possible embodiment of the present disclosure, the flexible thin film solar cell includes a solar cell made of copper indium gallium selenide.

According to one possible embodiment of the present disclosure, one or more locking hooks for securing the tarpaulin to the vehicle or the one or more outdoor devices are further provided on one or more sides of a plurality of sides of the tarpaulin.

According to one possible embodiment of the present disclosure, at least one cable outlet for connecting the one or more loads is further provided on the tarpaulin.

According to one possible embodiment of the present disclosure, the tarpaulin is a polyvinyl chloride coated fabric.

In a second aspect, an embodiment of the present disclosure provides a solar tent that includes a tarpaulin solar energy generation system applied to one or more loads inside a vehicle or one or more outdoor devices, the tarpaulin solar energy generation system including a tarpaulin, one or more solar components, a controller and an energy storage battery; wherein the one or more solar components are secured to the tarpaulin and adapted to receive light energy; the controller is connected to each of the energy storage battery and the solar components and adapted to convert electrical energy generated by the solar components and to store the converted electrical energy in the energy storage battery; and the solar tent is formed by opening the tarpaulin of the tarpaulin solar energy generation system and fixing the tarpaulin on which the one or more solar components are secured to a support.

According to one possible embodiment of the present disclosure, one or more mounting holes for securing the tarpaulin to the vehicle or the one or more outdoor devices are provided on one or more sides of a plurality of sides of the tarpaulin.

According to one possible embodiment of the present disclosure, each of the one or more mounting holes is provided with a metal ring fixed therein.

According to one possible embodiment of the present disclosure, the metal ring is a ring made of aluminum.

According to one possible embodiment of the present disclosure, the solar component is a flexible solar component.

According to one possible embodiment of the present disclosure, the flexible solar component includes a flexible thin film solar cell.

According to one possible embodiment of the present disclosure, the flexible thin film solar cell includes a solar cell made of copper indium gallium selenide.

According to one possible embodiment of the present disclosure, one or more locking hooks for securing the tarpaulin to the vehicle or the outdoor device are further provided on one or more sides of a plurality of sides of the tarpaulin.

According to one possible embodiment of the present disclosure, at least one cable outlet for connecting the one or more loads is further provided on the tarpaulin.

According to one possible embodiment of the present disclosure, the tarpaulin is a polyvinyl chloride coated fabric.

### BRIEF DESCRIPTION OF THE DRAWINGS

The accompanying drawings, which constitute a part of the present disclosure, are used to provide a further understanding of the present disclosure, and exemplary embodiments of the present disclosure and description thereof are intended to explain the present disclosure, rather than to form inappropriate limitations thereof. In the drawings:

FIG. 1 is a first schematic view of a tarpaulin solar energy generation system provided in an embodiment of the present disclosure;

FIG. 2 is a second schematic view of the tarpaulin solar energy generation system provided in the embodiment of the present disclosure; and

FIG. 3 is a schematic view of a solar tent provided in an embodiment of the present disclosure.

### LIST OF REFERENCE SIGNS

1—tarpaulin; 2—solar component; 3—controller; 4—energy storage battery; 5—mounting hole; 6—support; 7—load; 8—vehicle body; 9—metal ring; 10—locking hook; 11—cable outlet; 12—solar tent

### DETAILED DESCRIPTION

To make the above objects, features and advantages of the embodiments of the present disclosure more readily appreciated, the present disclosure will be further described hereinafter in detail in conjunction with the accompanying drawings and the following specific embodiments.

It should be noted that terms “left”, “right”, “front”, “rear”, “head” or “tail” used in the embodiments of the present disclosure refer to the left side, the right side, the front side, the rear side, the head or the tail of the vehicle relative to its forward direction. However, it can be understood by a person skilled in the art that such terms “left”, “right”, “front”, “rear”, “head” or “tail” may also appropriately refer to sides relative to other directions of the vehicle, as desired, and the embodiments of the present disclosure are not limited to those as illustrated and described herein.

The present disclosure will be explained hereinafter in detail with reference to the drawings and in conjunction with the specific embodiments.

### First Embodiment

This embodiment of the present disclosure relates to a tarpaulin solar energy generation system applied to one or more loads inside a vehicle or one or more outdoor devices. The tarpaulin solar energy generation system includes a tarpaulin, one or more solar components, a controller and an energy storage battery. The one or more solar components are secured to the tarpaulin and adapted to receive light energy. The controller is connected to each of the energy storage battery and the solar components and adapted to convert electrical energy generated by the solar components and to store the converted electrical energy in the energy storage battery.

In this way, the tarpaulin solar energy generation system according to the embodiment of the present disclosure has at least the following advantages.

According to the first embodiment of the present disclosure, the tarpaulin in the tarpaulin solar energy generation system is lightweight, flexible and easy to fold. The tarpaulin to which the solar components are secured can thus be conveniently mounted to the vehicle or the outdoor devices. Moreover, the tarpaulin solar energy generation system is simple in its overall structure, relatively light, and easy to store and carry, and also ready to assemble or disassemble. In addition, the tarpaulin can be flexibly made depending on different sizes of vehicles and requirements of outdoor devices so that the tarpaulin solar energy generation system can be widely applied to a variety of applications.

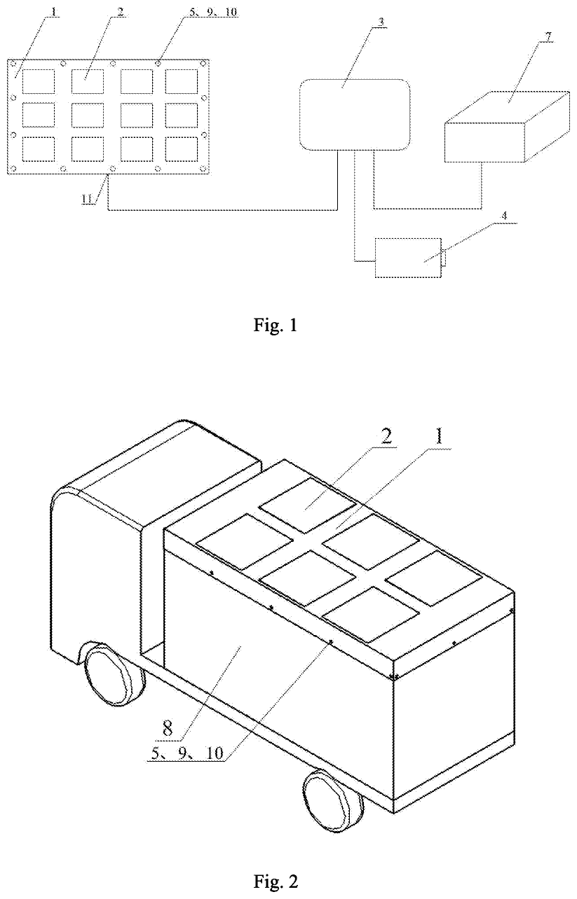

Reference is made to FIG. 1 that shows a first schematic view of the tarpaulin solar energy generation system provided in the embodiment of the present disclosure. The tarpaulin solar energy generation system can be applied to a vehicle, and may include a tarpaulin 1, one or more solar components 2, a controller 3 and an energy storage battery 4. The solar components 2 are secured to the tarpaulin 1 for receiving light energy. The controller 3 is connected to each of the solar components 2 and the energy storage battery 4, for converting electrical energy generated by the solar components 2 and storing the converted electrical energy in the energy storage battery. Here, for how to convert the received light energy into some form of electrical energy and perform proper storage, reference can be made to the energy conversion and storage technology that is available in the field of photovoltaic power generation technology, and details thereof will not be described herein.

Specifically, the solar components can be fixed to the tarpaulin by means of an adhesive or by printing. Naturally, other fixing methods are also possible, as long as the solar components can be fixed to the tarpaulin without damaging the solar components. The fixing manner is not particularly defined in the embodiments of the present disclosure.

As shown in FIG. 2, for example, if the tarpaulin solar energy generation system is applied to a vehicle, the tarpaulin 1 may be fixed to a top cover of a vehicle body 8 to receive light energy when there is sunlight in the daytime. The controller in the tarpaulin solar energy generation system will convert the solar energy into electrical energy and provide one or more in-vehicle loads 7 with electricity, and store the remaining electrical power in the energy storage battery 4 in preparation for use at night or on rainy days.

The tarpaulin solar energy generation system according to this embodiment of the present disclosure is simple in its overall structure, relatively light, and easy to store and carry, and also ready to assemble or disassemble. In addition, the tarpaulin 1 can be flexibly made depending on different sizes of vehicles and requirements of outdoor devices so that the tarpaulin solar energy generation system can be widely applied to a variety of applications.

In this embodiment of the present disclosure, one or more mounting holes for securing the tarpaulin to the vehicle or the one or more outdoor devices are provided on one or more sides of a plurality of sides of the tarpaulin. Specifically, as shown in FIG. 1, one or more mounting holes 5 are arranged around the tarpaulin 1. By inserting ropes or cables through the mounting holes 5, the tarpaulin 1 to which the solar components 2 are secured is fixed to the vehicle or the outdoor devices in such a manner that the tarpaulin 1 is smoothly and firmly mounted on the vehicle or the outdoor devices without affecting driving safety.

Optionally, as shown in FIG. 1, in this embodiment of the present disclosure, each of the one or more mounting holes 5 is provided with a metal ring 9 fixed therein. In a specific embodiment, the metal ring 9 may be a ring made of aluminum. Since aluminum is relatively light, will not rust in a humid environment and is relatively cheap, use of the aluminum ring not only will not make the tarpaulin heavier, but also will result in economic cost saving. Naturally, the metal ring 9 is not limited to being made of aluminum in the embodiments of the present disclosure, and may be also made of another metal having the same function as the aluminum.

In this embodiment of the present disclosure, the solar component may be a flexible solar component, for example. The flexible solar component includes, for example, a flexible thin film solar cell. The flexible thin film solar cell may be made of copper indium gallium selenide, for example. Due to the light weight and the foldability of the flexible photovoltaic power generation unit, when the solar component 2 is a flexible solar component in a practical application, it is possible to result in not only a lighter weight of the whole vehicle, but also even plentiful construction designs of the solar component 2, so as to increase the overall aesthetics of the vehicle.

Optionally, as shown in FIG. 1, in this embodiment of the present disclosure, one or more locking hooks 10 for securing the tarpaulin to the vehicle or the one or more outdoor devices are further provided on the one or more sides of the plurality of sides of the tarpaulin. In a practical application, mounting holes 5 may be arranged around the tarpaulin. Ropes or cables might be then inserted through the mounting holes 5 to secure the tarpaulin 1 with the solar components 2 secured thereto to the vehicle or the outdoor devices. Sometimes when parking and when there is no wind, people also can provide one or more locking hooks 10 around the tarpaulin and directly fix the locking hooks 10 to the vehicle or the outdoor device. This operation is very simple, and only requires some requirements on the structure of the vehicle body or of the outdoor device, that is, the vehicle body or the outdoor device may be required to have a structure that can fix the locking hook 10.

Furthermore, optionally, in this embodiment of the present disclosure, as shown in FIG. 1, at least one cable outlet 11 for connecting one or more loads 7 is further provided on the tarpaulin. A plurality of cable outlets 11 for connecting one or more in-vehicle loads 7 or other electronic devices may be provided on the tarpaulin. In this way, the function of the tarpaulin solar energy generation system is fully utilized to meet the needs of people.

Optionally, in this embodiment of the present disclosure, the tarpaulin is a polyvinyl chloride coated fabric. In case of the polyvinyl chloride coated fabric, some auxiliary materials such as plasticizer and anti-aging agent are added during its manufacturing process to enhance its heat resistance, toughness, ductility, etc. while also imparting weather resistance, water resistance and durability. Therefore, the tarpaulin solar energy generation system can be used for a long time. In order to prolong the service life, the tarpaulin solar energy generation system can be folded and stored in a storage box when not in use, and this will also make it convenient to carry.

### Second Embodiment

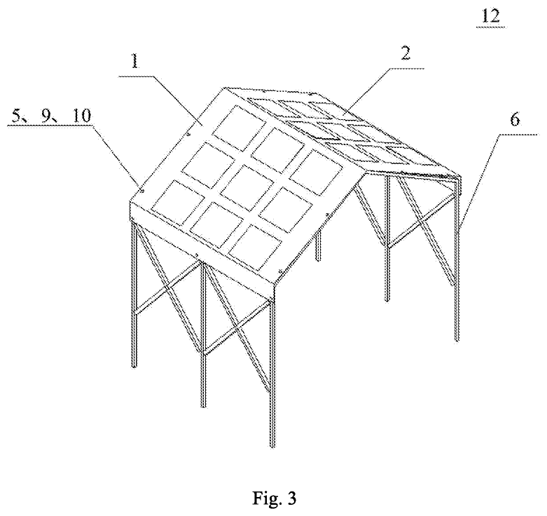

This embodiment of the present disclosure further provides a solar tent 12 that includes the tarpaulin solar energy generation system as described above. As shown in FIG. 3, in a practical application, when people go to the field or go outdoors for work or activities, and when the solar vehicle cannot be driven to the scheduled place, how to charge some office and living electronics that people often use is a major technical problem. At this time, people can open the tarpaulin 1 in the tarpaulin solar energy generation system and fix the tarpaulin 1 to which the solar components 2 have been secured to a support 6 with a rope or locking hooks, so as to form the tent 12. The tent 12 can absorb light energy in the sunlight, and the controller 3 can convert the light energy into electrical energy and store the electrical energy in the energy storage battery 4 in order to provide electricity guarantee for the electronics of people. In addition, when people encounter a heavy rain or are exposed to a blazing sun, the solar tent 12 can also shelter them from wind and rain, providing them with a more comfortable space for activities. Also, when the activities are over, the solar tent 12 is easy to disassemble. After the disassembly, the solar tent 12 may be folded and stored into a storage box, or may be also fixed on the vehicle to replenish electricity for the energy storage battery, so as to provide electricity guarantee for the in-vehicle loads.

To sum up, according to the second embodiment of the present disclosure, when the solar vehicle cannot reach a place where people do field or outdoor activities, the solar tent can solve the technical problem that the lack of electricity causes a lot of inconvenience. Moreover, when encountering bad weather such as a heavy rain or a blazing sun, people can use the solar tent to provide a more comfortable place to prevent the bad weather from bringing harm to people's health.

Finally, it should be also noted that in this context, relational terms such as first and second are used merely to distinguish one from another entity or action without necessarily requiring or implying any actual such relationship or order between entities or actions. Furthermore, the terms “comprising”, “including” or any other variants thereof are intended to be not exclusive such that the a process, method, article or terminal device including a series of elements not only includes the elements stated, but also other elements that are not explicitly listed, or elements inherent to the process, method, article or terminal device. Without further limitation, an element defined by the phase “comprising a . . . ” does not exclude the presence of additional identical elements in a process, method, article or terminal device that includes the element.

The tarpaulin solar energy generation system and the solar tent provided in the embodiments of the present disclosure have been described in detail above, and specific examples are provided herein to explain the principle of the embodiments and implementations. However, the above embodiments are merely used for the purpose of facilitating the understanding of the method of the embodiments and core idea thereof. Meanwhile, in light of the technical idea of the embodiments of the present disclosure, there can be a change in the specific embodiments and the scope of application for a person skilled in the art. To sum up, the contents of the present description should not be construed as any adverse limitations to the scope of the embodiments of the present disclosure.

What is claimed is:

1. A tarpaulin solar energy generation system applied to one or more loads inside a vehicle or one or more outdoor devices, the tarpaulin solar energy generation system comprising a tarpaulin, one or more solar components, a controller and an energy storage battery;
wherein the one or more solar components are secured to the tarpaulin and adapted to receive light energy; and
the controller is connected to each of the energy storage battery and the solar components and adapted to convert electrical energy generated by the solar components and to store the converted electrical energy in the energy storage battery.

2. The tarpaulin solar energy generation system according to claim 1, wherein one or more mounting holes for securing the tarpaulin to the vehicle or the one or more outdoor devices are provided on one or more sides of a plurality of sides of the tarpaulin.

3. The tarpaulin solar energy generation system according to claim 2, wherein each of the one or more mounting holes is provided with a metal ring fixed therein.

4. The tarpaulin solar energy generation system according to claim 3, wherein the metal ring is a ring made of aluminum.

5. The tarpaulin solar energy generation system according to claim 1, wherein the solar component is a flexible solar component.

6. The tarpaulin solar energy generation system according to claim 5, wherein the flexible solar component comprises a flexible thin film solar cell.

7. The tarpaulin solar energy generation system according to claim 6, wherein the flexible thin film solar cell comprises a solar cell made of copper indium gallium selenide.

8. The tarpaulin solar energy generation system according to claim 1, wherein one or more locking hooks for securing the tarpaulin to the vehicle or the one or more outdoor devices are further provided on one or more sides of a plurality of sides of the tarpaulin.

9. The tarpaulin solar energy generation system according to claim 1, wherein at least one cable outlet for connecting the one or more loads is further provided on the tarpaulin.

10. The tarpaulin solar energy generation system according to claim 1, wherein the tarpaulin is a polyvinyl chloride coated fabric.

11. A solar tent comprising a tarpaulin solar energy generation system applied to one or more loads inside a vehicle or one or more outdoor devices, the tarpaulin solar energy generation system comprising a tarpaulin, one or more solar components, a controller and an energy storage battery;
wherein the one or more solar components are secured to the tarpaulin and adapted to receive light energy;
the controller is connected to each of the energy storage battery and the solar components and adapted to convert electrical energy generated by the solar components and to store the converted electrical energy in the energy storage battery; and
the solar tent is formed by opening the tarpaulin of the tarpaulin solar energy generation system and fixing the tarpaulin on which the one or more solar components are secured to a support.

12. The solar tent according to claim 11, wherein one or more mounting holes for securing the tarpaulin to the vehicle or the one or more outdoor devices are provided on one or more sides of a plurality of sides of the tarpaulin.

13. The solar tent according to claim 12, wherein each of the one or more mounting holes is provided with a metal ring fixed therein.

14. The solar tent according to claim 13, wherein the metal ring is a ring made of aluminum.

15. The solar tent according to claim 11, wherein the solar component is a flexible solar component.

16. The solar tent according to claim 15, wherein the flexible solar component comprises a flexible thin film solar cell.

17. The solar tent according to claim 16, wherein the flexible thin film solar cell comprises a solar cell made of copper indium gallium selenide.

18. The solar tent according to claim 11, wherein one or more locking hooks for securing the tarpaulin to the vehicle or the outdoor device are further provided on one or more sides of a plurality of sides of the tarpaulin.

19. The solar tent according to claim 11, wherein at least one cable outlet for connecting the one or more loads is further provided on the tarpaulin.

20. The solar tent according to claim 11, wherein the tarpaulin is a polyvinyl chloride coated fabric.
